(19) United States
(12) Patent Application Publication
(10) Pub. No.: US 2025/0273920 A1
(43) Pub. Date: Aug. 28, 2025

(54) CONTROLLER, LASER DEVICE, AND ELECTRONIC DEVICE MANUFACTURING METHOD

(71) Applicant: Gigaphoton Inc., Tochigi (JP)

(72) Inventors: Motomu KATO, Oyama-shi (JP); Kazuhiro SUZUKI, Oyama-shi (JP)

(73) Assignee: Gigaphoton Inc., Tochigi (JP)

(21) Appl. No.: 19/016,756

(22) Filed: Jan. 10, 2025

(30) Foreign Application Priority Data
Feb. 28, 2024 (JP) 2024-028027

(51) Int. Cl. H01S 3/09; G03F 7/00

(52) U.S. Cl. CPC H01S 3/09; G03F 7/70025; G03F 7/7055

(57) ABSTRACT

A controller includes a processor, a volatile memory, a nonvolatile memory, and a capacitor, and is configured to control a laser device. Here, the processor is configured to store a parameter of the laser device in the volatile memory when receiving power supply from outside the controller, and when the power supply from outside is stopped, store, in the nonvolatile memory, the parameter stored in the volatile memory and information indicating a duration time of power supply from the capacitor while receiving the power supply from the capacitor.

### CROSS-REFERENCE TO RELATED APPLICATIONS

The present application claims the benefit of Japanese Patent Application No. 2024-028027, filed on Feb. 28, 2024, the entire contents of which are hereby incorporated by reference.

### BACKGROUND

### 1. Technical Field

The present disclosure relates to a controller, a laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. A gas laser device with a narrowed spectral line width is referred to as a line narrowing gas laser device.

### LIST OF DOCUMENTS

### Patent Documents

Patent Document 1: Japanese Patent Application Publication No. 2022-136817

### SUMMARY

A controller according to an aspect of the present disclosure includes a processor, a volatile memory, nonvolatile memory, and a capacitor, and is configured to control a laser device. Here, the processor is configured to store a parameter of the laser device in the volatile memory when receiving power supply from outside the controller, and when the power supply from outside is stopped, store, in the nonvolatile memory, the parameter stored in the volatile memory and information indicating a duration time of power supply from the capacitor while receiving the power supply from the capacitor.

A laser device according to an aspect of the present disclosure includes an oscillator configured to output laser light, and a controller configured to control the oscillator. Here, the controller includes a processor, a volatile memory, a nonvolatile memory, and a capacitor. The processor is configured to store a parameter of the laser device in the volatile memory when receiving power supply from outside the controller, and when the power supply from outside is stopped, store, in the nonvolatile memory, the parameter stored in the volatile memory and information indicating a duration time of power supply from the capacitor while receiving the power supply from the capacitor.

An electronic device manufacturing method according to an aspect of the present disclosure includes generating laser light using a laser device, outputting the laser light to an exposure apparatus, and exposing a photosensitive substrate to the laser light in the exposure apparatus to manufacture an electronic device. Here, the laser device includes an oscillator configured to output laser light, and a controller configured to control the oscillator. The controller includes a processor, a volatile memory, a nonvolatile memory, and a capacitor. The processor is configured to store a parameter of the laser device in the volatile memory when receiving power supply from outside the controller, and when the power supply from outside is stopped, store, in the nonvolatile memory, the parameter stored in the volatile memory and information indicating a duration time of power supply from the capacitor while receiving the power supply from the capacitor.

### BRIEF DESCRIPTION OF THE DRAWINGS

Embodiments of the present disclosure will be described below merely as examples with reference to the accompanying drawings.

FIG. 1 shows the configuration of an exposure system in a comparative example.

FIG. 2 shows the configuration of a laser device according to the comparative example.

FIG. 3 is a flowchart showing operation of a processor when an internal power source becomes off in a first embodiment.

FIG. 4 shows data of a part of a nonvolatile memory in the first embodiment.

FIG. 5 is a flowchart showing operation of the processor when the internal power source becomes on in the first embodiment.

FIG. 6 is a flowchart showing operation of the processor when the internal power source becomes off in a second embodiment.

FIG. 7 shows data of a part of the nonvolatile memory in the second embodiment.

### DESCRIPTION OF EMBODIMENTS

### <Contents>

1. Comparative example
   1.1 Configuration of exposure apparatus 200
   1.2 Operation of exposure apparatus 200
   1.3 Configuration of laser device 100
   1.4 Operation of laser device 100
   1.5 Problem of comparative example
2. Laser device 100 determining deterioration based on duration time of power supply from capacitor 24
   2.1 Operation when power source becomes off
   2.2 Operation when power source becomes on
   2.3 Effect
3. Laser device 100 sequentially storing information indicating duration time in different regions of nonvolatile memory 23
   3.1 Operation when power source becomes off
   3.2 Operation when power source becomes on
   3.3 Effect
4. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

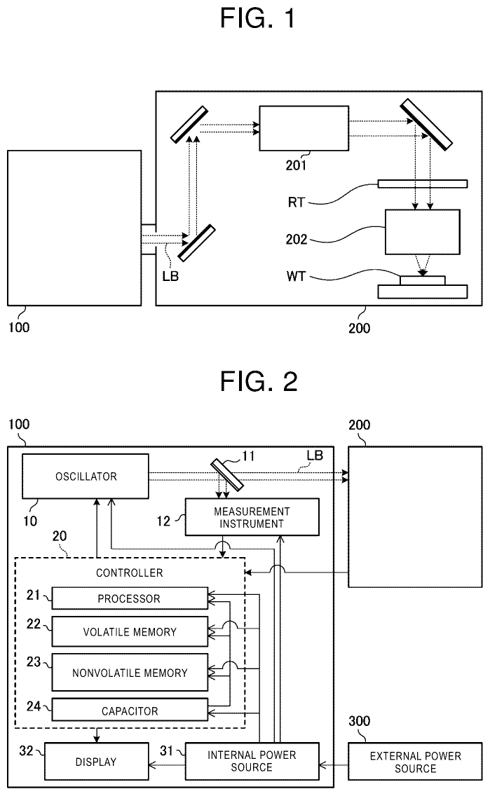

FIG. 1 shows the configuration of an exposure system in a comparative example. The comparative example of the present disclosure is an example recognized by the applicant as known only by the applicant, and is not a publicly known example admitted by the applicant.

The exposure system includes a laser device 100 and an exposure apparatus 200. The laser device 100 is configured to output laser light LB toward the exposure apparatus 200.

### 1.1 Configuration of Exposure Apparatus 200

The exposure apparatus 200 includes an illumination optical system 201 and a projection optical system 202. The illumination optical system 201 illuminates a reticle pattern of a reticle (not shown) arranged on a reticle stage RT with the laser light LB incident from the laser device 100. The projection optical system 202 causes the laser light LB transmitted through the reticle to be imaged as being reduced and projected on a workpiece (not shown) arranged on a workpiece table WT. The workpiece is a photosensitive substrate such as a semiconductor wafer on which a resist film is applied.

### 1.2 Operation of Exposure Apparatus 200

The exposure apparatus 200 synchronously translates the reticle stage RT and the workpiece table WT in directions opposite to each other. Thus, the workpiece is exposed to the laser light LB reflecting the reticle pattern. Through the exposure process as described above, the reticle pattern is transferred onto the semiconductor wafer. Thereafter, an electronic device can be manufactured through a plurality of processes.

Instead of the exposure apparatus 200, laser processing may be performed by causing the laser light LB output from the laser device 100 to enter a laser processing device (not shown).

### 1.3 Configuration of Laser Device 100

FIG. 2 shows the configuration of the laser device 100 according to the comparative example. The laser device 100 includes an oscillator 10, a beam splitter 11, a measurement instrument 12, a controller 20, an internal power source 31, and a display 32.

The oscillator 10 is a device that includes a laser medium (not shown) and a laser resonator (not shown) and outputs the laser light LB. The beam splitter 11 is arranged on an optical path of the laser light LB, and transmits a part of the laser light LB at high transmittance and reflects the other part. The measurement instrument 12 is arranged on the optical path of the light reflected by the beam splitter 11, and outputs measurement values such as the energy, the center wavelength, and the spectral line width of the light.

The controller 20 includes a processor 21, a volatile memory 22, a nonvolatile memory 23, and a capacitor 24, and controls the entire laser device 100 including the oscillator 10. The controller 20 is specifically configured or programmed to perform various processes included in the present disclosure. The processor 21 is a processing device that executes various programs stored in the nonvolatile memory 23. The volatile memory 22 is a storage device such as a random access memory (RAM) that serves as a temporary storage when the processor 21 operates. The nonvolatile memory 23 is a storage device such as a flash memory that stores various programs and data to be taken over before and after a power source is interrupted. The capacitor 24 is a device that stores electric energy when the internal power source 31 is on, and supplies power to the processor 21, the volatile memory 22, and the nonvolatile memory 23 when the internal power source 31 becomes off.

The internal power source 31 is a device that, when the laser device 100 is in operation, receives power supply from an external power source 300, adjusts a voltage and converts the voltage into a direct-current voltage, and supplies power to each unit of the laser device 100. When the laser device 100 is not in operation, power supply from the internal power source 31 to each unit of the laser device 100 is stopped. The internal power source 31 corresponds to the outside of the controller 20 in the present disclosure. The display 32 is a device that displays various images and characters in accordance with an image generation signal output from the controller 20.

### 1.4 Operation of Laser Device 100

The controller 20 controls the oscillator 10 based on a target value such as the target energy, the target center wavelength, and the target spectral line width received from the exposure apparatus 200 and a measurement value acquired from the measurement instrument 12. While performing such control, the controller 20 stores, in the volatile memory 22, a parameter including either or both of a setting value for operating hardware and software of the laser device 100 and a measurement value acquired from the measurement instrument 12.

When a user or an operator of the laser device 100 stops the operation of the laser device 100, or when power supply from the external power source 300 is interrupted due to power failure or the like, the internal power source 31 also becomes off, and power supply to the controller 20 is stopped. When the power supply is stopped, data in the volatile memory 22 disappears. However, since the parameter stored in the volatile memory 22 contains information useful for subsequent operation of the laser device 100, it is necessary to take a backup thereof. Therefore, when the internal power source 31 becomes off, backup to the nonvolatile memory 23 is performed using the power supplied from the capacitor 24 to each unit of the controller 20. In the next operation of the laser device 100, the previous parameter can be taken over by reading out data from the nonvolatile memory 23.

### 1.5 Problem of Comparative Example

The capacitor 24 may deteriorate over time, and power supply capability from the capacitor 24 may be reduced. When the power supply capability is reduced and, for example, the power supply is stopped during backup, not only the backup process is not completed, but also a part of the data in the nonvolatile memory 23 may be damaged. Therefore, it is necessary to determine deterioration of the capacitor 24 and replace the capacitor 24 before failure occurs.

To determine deterioration of the capacitor 24, it is conceivable to measure the output voltage of the capacitor 24. However, providing a mechanism for measuring the output voltage of the capacitor 24 separately may lead to an increase in the size and cost of the controller 20.

The embodiments described below relate to determining deterioration of the capacitor 24 in a simple device configuration.

### 2. Laser Device 100 Determining Deterioration Based on Duration Time of Power Supply from Capacitor 24

2.1 Operation when Power Source Becomes Off

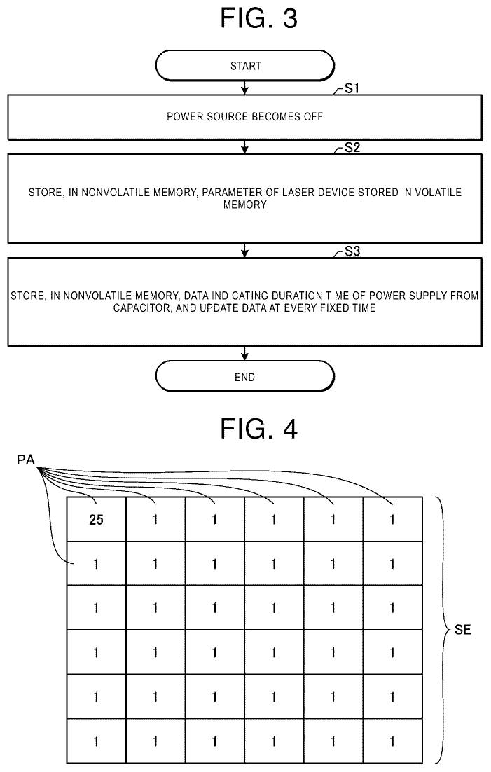

FIG. 3 is a flowchart showing operation of the processor 21 when the internal power source 31 becomes off in a first embodiment. The configurations of the laser device 100 and the controller 20 in the first embodiment are similar to those in the comparative example.

In S1, when the internal power source 31 becomes off, the processor 21, the volatile memory 22, and the nonvolatile memory 23 start operation with the power supplied from the capacitor 24.

In S2, the processor 21 stores, in the nonvolatile memory 23, the parameter of the laser device 100 stored in the volatile memory 22. Up to this point, the first embodiment is similar to the comparative example.

In S3, the processor 21 stores data indicating the duration time of the power supply from the capacitor 24 in the nonvolatile memory 23, and updates the data at every fixed time. The process of S3 may be performed in parallel with storing the parameter in the nonvolatile memory 23 in S2, but is preferably performed after the process of S2 is completed. The duration time stored in the nonvolatile memory 23 may be a time from when the internal power source 31 becomes off or a time from when storing the parameter in the nonvolatile memory 23 in S2 is completed.

The data of the duration time is updated to a large numerical value as time elapses. Updating the data is repeated until the power supply from the capacitor 24 necessary for the operation of the processor 21 is stopped.

Updating data means overwriting data, and the data of the duration time stored before the updating may be erased. When the power supply from the capacitor 24 is stopped, the data cannot be updated, and only the latest data remains in the nonvolatile memory 23. Therefore, the data of the duration time stored in the nonvolatile memory 23 at the time when the power supply from the capacitor 24 is stopped indicates the power supply capability of the capacitor 24.

The measurement accuracy of the duration time depends on the fixed time in S3. The fixed time is preferably 3 seconds or less, and may be, for example, 1 second. For example, the data of the duration time may be updated by adding 1 for each second with the value at the end of S2 being 0, and in this case, corresponds to the data obtained by truncating a decimal in the number of seconds from the end of $2 until the power supply is stopped.

When the power supply from the capacitor 24 is stopped, processing of the present flowchart is ended.

FIG. 4 shows data of a part of the nonvolatile memory 23 in the first embodiment. The nonvolatile memory 23 includes a plurality of sectors SE. One sector SE includes a plurality of pages PA. The page PA is the smallest unit of data for writing and reading in the nonvolatile memory 23. The sector SE is the smallest unit of data erasure in the nonvolatile memory 23. That is, although writing and reading of data can be performed for each page PA, data erasure is performed for all pages PA included in one sector SE and cannot be performed for each page PA. Since data overwriting also involves data erasure, the sector SE is the smallest unit thereof.

In S3 of FIG. 3, among the plurality of sectors SE included in the nonvolatile memory 23, a free sector in which various programs or the parameter stored in S2 is not stored is selected. The data of the duration time of the power supply may be stored in one page PA of the selected sector SE. Alternatively, the data of the duration time may be stored in a nonvolatile memory 23 different from the nonvolatile memory 23 in which the various programs or the parameter is stored.

2.2 Operation when Power Source Becomes on

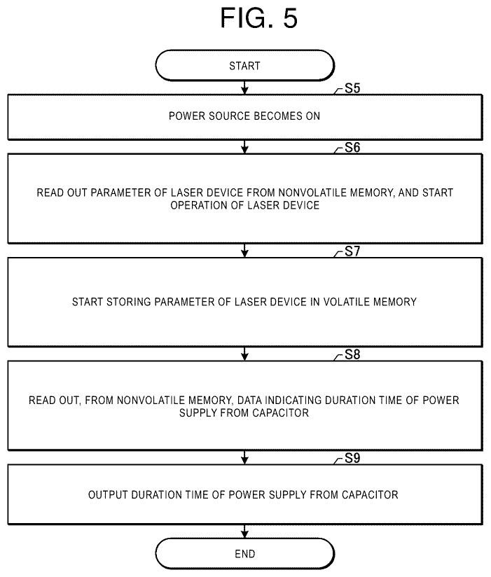

FIG. 5 is a flowchart showing the operation of the processor 21 when the internal power source 31 becomes on in the first embodiment.

In S5, when the internal power source 31 becomes on, the processor 21, the volatile memory 22, and the nonvolatile memory 23 start operation with the power supplied from the internal power source 31.

In S6, the processor 21 reads out the parameter of the laser device 100 stored at the previous off-time of the internal power source 31 from the nonvolatile memory 23, and causes the laser device 100 to start operation.

In S7, the processor 21 starts storing the parameter of the laser device 100 in the volatile memory 22. The parameter is stored in the volatile memory 22 every time the parameter is newly acquired during the operation of the laser device 100.

In S8, the processor 21 reads out, from the nonvolatile memory 23, the data indicating the duration time of the power supply from the capacitor 24 stored at the previous off-time of the internal power source 31.

In S9, the processor 21 outputs the data indicating the duration time of the power supply from the capacitor 24. The data indicating the duration time may be displayed on the display 32, or may be stored as log data in the nonvolatile memory 23 or another storage device. A user or an operator of the laser device 100 may determine deterioration of the capacitor 24 based on the data indicating the duration time.

The processor 21 may determine deterioration of the capacitor 24 based on the data indicating the duration time. For example, the degree of deterioration or necessity of replacement of the capacitor 24 may be determined based on whether or not the duration time has become shorter than a threshold, whether or not the duration time has become equal to or less than a certain ratio with respect to the value of the capacitor 24 when it was new, or whether or not the duration time has become equal to or less than a certain ratio with respect to a design value. Further, by referring to the log data related to the duration time, the time when the replacement is necessary may be predicted from the transition of the duration time. The determination result of such deterioration may be displayed on the display 32, or may be stored as log data in the nonvolatile memory 23 or another storage device.

After S9, the processor 21 ends processing of the present flowchart.

### 2.3 Effect

(1) According to the first embodiment, the controller 20 includes the processor 21, the volatile memory 22, the nonvolatile memory 23, and the capacitor 24, and controls the laser device 100. The processor 21 stores the parameter of the laser device 100 in the volatile memory 22 while receiving power supply from the internal power source 31. The processor 21 receives power supply from the capacitor 24 when the power supply from the internal power source 31 is stopped, and stores, in the nonvolatile memory 23, the parameter stored in the volatile memory 22 and the information indicating the duration time of the power supply from the capacitor 24.

Accordingly, by storing the information indicating the duration time of the power supply from the capacitor 24 in the nonvolatile memory 23, it is possible to determine the deterioration of the capacitor 24 with a simple device configuration without using a voltmeter.

(2) According to the first embodiment, the processor 21 stores the information indicating the duration time in the nonvolatile memory 23 after storing the parameter in the nonvolatile memory 23 is completed.

Accordingly, by giving priority to the backup of the parameter, the backup can be reliably completed before the power supply from the capacitor 24 is stopped.

(3) According to the first embodiment, the processor 21 repeats the operation of storing the information indicating the duration time in the nonvolatile memory 23 until the power supply from the capacitor 24 necessary for the operation of the processor 21 is stopped.

Accordingly, the power supply capability of the capacitor 24 can be known by repeating the storing until the power supply is stopped.

(4) According to the first embodiment, the processor 21 repeats the operation of sequentially updating the information indicating the duration time stored in the nonvolatile memory 23.

Accordingly, it is possible to know an accurate duration time by repeating the updating to the latest data.

(5) According to the first embodiment, the processor 21 updates the information indicating the duration time at every fixed time.

Accordingly, it is possible to keep the measurement accuracy of the duration time constant.

(6) According to the first embodiment, the parameter includes any one of a setting value for operating the laser device 100 and a measurement value acquired from the measurement instrument 12 of the laser device 100.

Accordingly, by reliably performing back up of the parameter including the set value or the measurement value, the laser device 100 can be operated by taking over the immediately preceding parameter at the next startup.

(7) According to the first embodiment, the processor 21 reads out the information indicating the duration time stored in the nonvolatile memory 23 when the power supply from the internal power source 31 is resumed.

Accordingly, it is possible to determine the deterioration of the capacitor 24 by reading out the duration time.

(8) According to the first embodiment, the processor 21 causes the display 32 to display the information indicating the duration time.

Accordingly, it is possible for a user or an operator to determine the deterioration of the capacitor 24 by showing the duration time to the user or the operator.

(9) According to the first embodiment, the processor 21 stores the information indicating the duration time as log data.

Accordingly, a user or an operator can confirm the duration time at a later date. Further, by recording the transition of the duration time, it is possible to accurately predict timing when replacement of the capacitor 24 is necessary.

(10) According to the first embodiment, the processor 21 determines the deterioration of the capacitor 24 based on the information indicating the duration time stored in the nonvolatile memory 23 when the power supply from the internal power source 31 is resumed.

Accordingly, it is possible to appropriately determine whether or not it is necessary to replace the capacitor 24 by determining the deterioration.

(11) According to the first embodiment, the processor 21 causes the display 32 to display the determination result of the deterioration of the capacitor 24.

Accordingly, the determination result can be indicated to a user or an operator.

(12) According to the first embodiment, the processor 21 stores the determination result of the deterioration of the capacitor 24 as log data.

Accordingly, a user or an operator can confirm the determination result at a later date. Further, by recording the transition of the determination result of the deterioration, it is possible to accurately predict timing when replacement of the capacitor 24 is necessary.

In other respects, the first embodiment is similar to the comparative example.

### 3. Laser Device 100 Sequentially Storing Information Indicating Duration Time in Different Regions of Nonvolatile Memory 23

3.1 Operation when Power Source Becomes Off

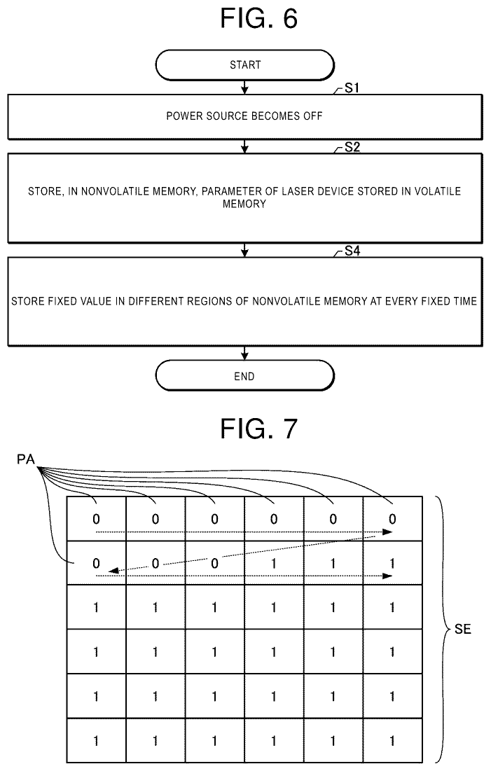

FIG. 6 is a flowchart showing the operation of the processor 21 when the internal power source 31 becomes off in a second embodiment. The configurations of the laser device 100 and the controller 20 in the second embodiment are similar to those in the comparative example. The processes of S1 and S2 are similar to those in the first embodiment.

After S2, in S4, the processor 21 stores data other than an initial value in different regions of the nonvolatile memory 23 at every fixed time. The different regions are, for example, different pages PA in the same sector SE. The process of S4 may be performed in parallel with storing the parameter in the nonvolatile memory 23 in S2, but is preferably performed after the process of S2 is completed. The process of S4 is repeated until the power supply from the capacitor 24 necessary for the operation of the processor 21 is stopped. When the power supply from the capacitor 24 is stopped, the process of the present flowchart is ended.

FIG. 7 shows data of a part of the nonvolatile memory 23 in the second embodiment. First, data of the selected sector SE, which is a free sector, is reset. For example, an initial value “1” is stored in all pages PA included in the selected sector SE. Next, in S4, data is stored in a different page PA at every fixed time. When the page PA containing data other than the initial value “1” is overwritten, the entire sector SE must be reset. However, when data is stored in the page PA containing the initial value “1”, other pages PA are not affected. The data to be stored is preferably a fixed value and, for example, a value “0” is stored. In FIG. 7, the initial value “1” is changed to the value “0” in order from the page PA at the upper left end.

3.2 Operation when Power Source Becomes on

The operation of the processor 21 when the power source becomes on is substantially the same as that in FIG. 5. However, in S8, the data of the duration time of the power supply is given in terms of the number of the pages PA in which the value “0” is stored. The longer the duration time, the greater the number of the pages PA in which the value “0” is stored. The processor 21 counts the number of the pages PA in which the value “0” is stored in the selected sector SE. In S9, the processor 21 calculates and outputs the duration time by multiplying the number of the pages PA in which the value “0” is stored by the length of the fixed time in S4 of FIG. 6. If there is any page PA in which neither the initial value “1” nor the value “0” is stored, it can be determined that the page PA is damaged.

### 3.3 Effect

(13) According to the second embodiment, the processor 21 repeats the operation of sequentially storing data related to the information indicating the duration time in a different page PA of the nonvolatile memory 23.

Accordingly, even when data in the n-th page PA is damaged as the power supply from the capacitor 24 is terminated while the data is being stored in the n-th page PA, the data in the n−1-th page PA remains, so that the information indicating the duration time can be reliably maintained.

(14) According to the second embodiment, the processor 21 stores data at every fixed time.

Accordingly, it is possible to keep the measurement accuracy of the duration time constant.

(15) According to the second embodiment, the processor 21 resets all the pages PA of at least one free sector included in the nonvolatile memory 23 being different from the sector in which the parameter is stored, and then stores the data in the free sector.

Accordingly, it is possible to store the information indicating the duration time without affecting the sector SE in which the parameter is stored.

(16) According to the second embodiment, the processor 21 acquires the duration time based on the number of the pages PA in which data other than the initial value is stored, when the power supply from the internal power source 31 is resumed.

Accordingly, since the number of the pages PA in which the data is stored increases as the duration time increases, the duration time can be accurately measured.

(17) According to the second embodiment, the processor 21 stores the data at every fixed time, and acquires the duration time based on the number of the pages PA in which the data is stored and the length of the fixed time when the power supply from the internal power source 31 is resumed.

Accordingly, since the data is stored at every fixed time, the accurate duration time can be known by multiplying the number of the pages PA in which the data is stored by the length of the fixed time.

(18) According to the second embodiment, the processor 21 repeats the operation of sequentially storing the same data in a different page PA of the nonvolatile memory 23.

Accordingly, the processing is simplified because the data is the same. Further, it is easy to determine whether or not the data is damaged.

In other respects, the second embodiment is similar to the first embodiment.

### 4. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A controller comprising a processor, a volatile memory, a nonvolatile memory, and a capacitor, and configured to control a laser device,
the processor being configured to store a parameter of the laser device in the volatile memory when receiving power supply from outside the controller, and when the power supply from outside is stopped, store, in the nonvolatile memory, the parameter stored in the volatile memory and information indicating a duration time of power supply from the capacitor while receiving the power supply from the capacitor.

2. The controller according to claim 1,
wherein the processor stores the information indicating the duration time in the nonvolatile memory after storing the parameter in the nonvolatile memory is completed.

3. The controller according to claim 1,
wherein the processor repeats operation of storing the information indicating the duration time in the nonvolatile memory until the power supply from the capacitor necessary for operation of the processor is stopped.

4. The controller according to claim 1,
wherein the processor repeats operation of sequentially updating the information indicating the duration time stored in the nonvolatile memory.

5. The controller according to claim 4,
wherein the processor updates the information indicating the duration time at every fixed time.

6. The controller according to claim 1,
wherein the parameter includes any one of a set value for operating the laser device and a measurement value acquired from a measurement instrument of the laser device.

7. The controller according to claim 1,
wherein the processor reads out the information indicating the duration time stored in the nonvolatile memory when the power supply from outside is resumed.

8. The controller according to claim 7,
wherein the processor causes a display to display the information indicating the duration time.

9. The controller according to claim 7,
wherein the processor stores the information indicating the duration time as log data.

10. The controller according to claim 1,
wherein the processor determines deterioration of the capacitor based on the information indicating the duration time stored in the nonvolatile memory when the power supply from outside is resumed.

11. The controller according to claim 10,
wherein the processor causes a display to display a determination result of the deterioration of the capacitor.

12. The controller according to claim 10,
wherein the processor stores a determination result of the deterioration of the capacitor as log data.

13. The controller according to claim 1,
wherein the processor repeats operation of sequentially storing data related to the information indicating the duration time in a different region of the nonvolatile memory.

14. The controller according to claim 13,
wherein the processor stores the data at every fixed time.

15. The controller according to claim 13,
wherein the processor resets all regions of at least one free sector included in the nonvolatile memory being different from a sector in which the parameter is stored, and then stores the data in the free sector.

16. The controller according to claim 13,
wherein the processor acquires the duration time based on a number of regions in which the data is stored when the power supply from outside is resumed.

17. The controller according to claim 13,
wherein the processor stores the data at every fixed time, and when the power supply from outside is resumed, acquires the duration time based on a number of regions in which the data is stored and a length of the fixed time.

18. The controller according to claim 1,
wherein the processor repeats operation of sequentially storing same data in a different region of the nonvolatile memory.

19. A laser device comprising an oscillator configured to output laser light, and a controller configured to control the oscillator,
the controller including a processor, a volatile memory, a nonvolatile memory, and a capacitor, and
the processor being configured to store a parameter of the laser device in the volatile memory when receiving power supply from outside the controller, and when the power supply from outside is stopped, store, in the nonvolatile memory, the parameter stored in the volatile memory and information indicating a duration time of power supply from the capacitor while receiving the power supply from the capacitor.

20. An electronic device manufacturing method, comprising:
generating laser light using a laser device;
outputting the laser light to an exposure apparatus; and
exposing a photosensitive substrate to the laser light in the exposure apparatus to manufacture an electronic device,
the laser device including an oscillator configured to output laser light, and a controller configured to control the oscillator,
the controller including a processor, a volatile memory, a nonvolatile memory, and a capacitor, and
the processor being configured to store a parameter of the laser device in the volatile memory when receiving power supply from outside the controller, and when the power supply from outside is stopped, store, in the nonvolatile memory, the parameter stored in the volatile memory and information indicating a duration time of power supply from the capacitor while receiving the power supply from the capacitor.
